(19) United States
(12) Patent Application Publication
(10) Pub. No.: US 2017/0194564 A1
(43) Pub. Date: Jul. 6, 2017

(54) FRAME FOR MOUNTING MASK PLATE, MASK PLATE DEVICE AND METHOD FOR FIXING MASK PLATE USING FRAME FOR MOUNTING MASK PLATE

(71) Applicants: BOE TECHNOLOGY GROUP CO., LTD., Beijing (CN); ORDOS YUANSHENG OPTOELECTRONICS CO., LTD., Ordos (CN)

(72) Inventors: Qun MA, Beijing (CN); Luijiang HUANGFU, Beijing (CN); Chonkyu MIN, Beijing (CN); Fengli JI, Beijing (CN)

(73) Assignees: BOE TECHNOLOGY GROUP CO., LTD., Beijing (CN); ORDOS YUANSHENG OPTOELECTRONICS CO., LTD., Beijing (CN)

(21) Appl. No.: 15/235,700

(22) Filed: Aug. 12, 2016

(30) Foreign Application Priority Data
Jan. 4, 2016 (CN) 201610005579.X

(51) Int. Cl. H01L 51/00

(52) U.S. Cl. CPC H01L 51/0011; H01L 2227/326

(57) ABSTRACT

The present disclosure provides a frame for mounting mask plates and a method for fixing a mask plate using the frame. The frame includes a frame body and a pulling unit at a first border portion of the frame body. The pulling unit includes a sliding block for connecting the mask plate and a guide mechanism through which the sliding block slides along a direction perpendicular to the first border portion.

### CROSS-REFERENCE TO RELATED APPLICATION

This application claims a priority to Chinese Patent Application No. 201610005579.X filed on Jan. 4, 2016, the disclosures of which are incorporated in their entirety by reference herein.

### TECHNICAL FIELD

The present disclosure relates to the field of organic light-emitting diode display technology, and in particular to a frame for mounting mask plates, a mask plate device and a method for fixing mask plates using a frame for mounting mask plates.

### BACKGROUND

The organic light-emitting diode (OLED) display is generally recognized as a third-generation display technology in the industry as the advantages of being light and thin, capable of emitting light actively, responding rapidly, having a wide viewing range, a low brightness and low power consumption and so on. The OLED display can be widely applied to cell phones, televisions and on-board devices.

During the process of manufacturing an OLED panel, a mask plate is generally fixed onto a frame by welding. In the actual practice, the mask plate needs to be removed and then rewelded or even replaced in the case that the mask plate is not stretched. However, a process of mounting and replacing the mask plate in the related art is very complicated, thereby increasing a manufacturing cost of the OLED panel.

### SUMMARY

In view of this, the present disclosure provides a frame for mounting a mask plate, a mask plate device and a method for fixing a mask plate using a frame for mounting a mask plate.

In a first aspect, a frame for mounting a mask plate is provided, including a frame body and at least one pulling unit at a first border portion of the frame body. The pulling unit includes a sliding block for connecting the mask plate and a guide mechanism through which the sliding block slides along a direction perpendicular to the first border portion, and the first border portion is configured to install the mask plate.

Optionally, the frame further includes at least one pulling unit at a second border portion of the frame body which is parallel to the first border portion thereof, the pulling unit at the second border portion is opposite to the pulling unit at the first side border portion.

Optionally, there exists a plurality of pulling units at both the first and second border portions.

Optionally, the guide mechanism includes a guide rail arranged on the frame body.

Optionally, the sliding block is made of metal.

Optionally, the pulling unit further includes a fixing component on the sliding block and configured to the install the mask plate onto the sliding block.

Optionally, the pulling unit further includes a driving mechanism configured to drive the sliding block to slide.

Optionally, the driving mechanism includes a leading screw and a twisting handle connected to the leading screw.

Optionally, the driving mechanism includes a leading screw and a servo motor connected to the leading screw.

In a second aspect, a method for fixing a mask plate using the frame hereinabove is provided, including: fixing an end of the mask plate onto the sliding block of the pulling unit at the first border portion; and sliding the sliding block until the mask plate is tightened.

Optionally, the method further includes: when the mask plate is loose, sliding the sliding block until the mask plate is tightened.

A mask plate device is further provided by the present disclosure, including: a frame for mounting a mask plate; and at least one mask plate movably installed on the frame. The frame includes a frame body with a first border portion and a second border portion, and at least one pulling unit arranged at the first border portion. The pulling unit includes a guide mechanism at the first border portion and a sliding block slidably installed on the guide mechanism. A first end of the mask plate is connected to the sliding block, and a second end thereof is connected to the second border portion.

Optionally, the first border portion is parallel to the second border portion.

Optionally, the first end of the mask plate is connected to the sliding block by welding.

Optionally, the first end of the mask plate is detachably connected to the sliding block.

Optionally, the frame further includes at least one pulling unit arranged at the second border portion. The pulling unit arranged at the second border portion includes a guide mechanism arranged at the second border portion and a sliding block slidably arranged on the guide mechanism at the second border portion. The second end of the mask plate is connected to the sliding block arranged at the second border portion.

Optionally, the first end of the mask plate is detachably connected to the sliding block arranged at the first border portion, and the second end of the mask plate is detachably connected to the sliding block arranged at the second border portion.

Optionally, the pulling unit further includes a driving mechanism configured to drive the sliding block to slide.

Optionally, the driving mechanism includes a leading screw and a twisting handle connected to the leading screw. The sliding block is provided with a nut sleeved on the leading screw.

Optionally, the driving mechanism includes a leading screw and a servo motor connected to the leading screw. The sliding block is provided with a nut sleeved on the leading screw.

According to the frame for mounting mask plates, at least one pulling unit is arranged at the first border portion. The pulling unit includes the sliding block connected to the mask plate and the guide mechanism configured to limit a sliding direction of the sliding block. When mounting the mask plate to the frame provided by the present disclosure, an end of the mask plate is fixed onto the sliding block of the pulling unit arranged at the first border portion, and then the sliding block is slid to tighten the mask plate. In compared with the related art, it is not required to apply an external force to the frame body to make it deformed towards its center or to maintain the external force until the welding of the mask plate is completed. Therefore, the manufacturing process is simpler than that in the related art. During the application, it is merely required to slide the sliding block and then tighten the mask plate once more, without removing the mask plate, in the case that the mask plate is loose. Therefore, the process of tightening the mask plate once more is very simple. In addition, it is not required to replace the mask plate, thereby saving the mask plate and reducing the manufacturing cost of the OLED panel.

### BRIEF DESCRIPTION OF THE DRAWINGS

The present disclosure will be described hereinafter in conjunction with drawings, so as to make the features and the advantages of the present disclosure more apparent. The following drawings are for illustrative purposes only, but shall not be used to limit the scope of the present disclosure.

FIG. 1 is a top view of a mask plate device;

FIG. 2 is a top view of a frame for mounting mask plates in some embodiments of the present disclosure.

FIG. 3 is a top view of a mask plate device including the frame for mounting mask plates shown in FIG. 2.

FIG. 4 is a top view of a frame for mounting mask plates in some embodiments of the present disclosure.

FIG. 5 is a top view of a mask plate device including the frame for mounting mask plates shown in FIG. 4.

FIG. 6 is a sectional view of a frame for mounting mask plates along a direction perpendicular to a first border portion in some embodiments of the present disclosure.

### DRAWING REFERENCE

10-frame; 20-mask plate; 100-frame body; 101-first border portion of the frame body; 102-pulling unit; 1021-sliding block of the pulling unit; 1022-guide mechanism of the pulling unit; 103-second border portion of the frame body; 104-leading screw; 105-servo motor; 200-mask plate

### DETAILED DESCRIPTION

In order to make the objects, the features and the advantages of the present disclosure more apparent, the present disclosure will be described in details hereinafter in conjunction with the drawings and embodiments. It should be noted that, the embodiments and the features therein may be combined without confliction.

The following description will be more specific, so as to facilitate understanding the present disclosure. However, the present disclosure may include other embodiments, so the following embodiments shall not be used to limit the scope of the present disclosure.

FIG. 1 is a top view of a mask plate device. As shown in FIG. 1, the mask plate device includes a frame 10 and a mask plate 20 welded onto the frame 10. The mask plate 20 may be a fine mask plate made of metal. One method for welding the mask plate 20 onto the frame 10 includes: applying an external force to the frame 10, so as to make the frame 10 to deform towards its center; welding two ends of a stretched mask plate 20 onto two opposite border portions of the frame 10 respectively; and releasing the external force applied to the frame 10. Finally, the mask plate 20 is stretched due to that the deformation of the frame 10 is recovered. In the actual practice of the mask plate device, the mask plate 20 needs to be removed and then rewelded or even replaced in the case that the mask plate 20 is not stretched. The process of mounting and replacing the mask plate in the related art is very complicated, thereby increasing the manufacturing cost of the OLED panel. If the mask plate needs to be replaced, the manufacturing cost of the OLED panel will be further increased.

In order to simplify the process of mounting and replacing the mask plate and reduce the manufacturing cost of the OLED panel, in a first aspect, a frame for mounting mask plates is provided by the present disclosure, including a frame body and at least one pulling unit arranged at a first border portion of the frame body. The pulling unit includes a sliding block for connecting the mask plate and a guide mechanism through which the sliding block slides along a direction perpendicular to the first border portion. The mask plate is fixed onto the first border portion.

According to the frame for mounting mask plates, at least one pulling unit is arranged at the first border portion. The pulling unit includes the sliding block for connecting the mask plate and the guide mechanism configured to limit a sliding direction of the sliding block. When mounting the mask plate to the frame for mounting mask plates provided by the present disclosure, an end of the mask plate is fixed onto the sliding block of the pulling unit arranged at the first border portion, and then the sliding block is slid to tense the mask plate. In compared with the related art, it is not required to apply an external force to the frame body to make it deformed towards its center or to maintain the external force until the welding of the mask plate is completed. Therefore, the manufacturing process is simpler than that in the related art. During the application, it is merely required to slide the sliding block and then tense the mask plate once more, without removing the mask plate, in the case that the mask plate is not stretched. Therefore, the process of tensing the mask plate once more is very simple. In addition, it is not required to replace the mask plate, thereby saving the mask plate and reducing the manufacturing cost of the OLED panel.

In a second aspect, a method for fixing a mask plate using the frame for mounting mask plates hereinabove is provided by the present disclosure, including: fixing an end of the mask plate onto the sliding block of the pulling unit arranged at the first border portion; and sliding the sliding block until the mask plate is stretched.

It can be seen that, the process of mounting the mask plate is very simple and easy to be implemented.

Furthermore, the method hereinabove further includes: sliding the sliding block until the mask plate is stretched in the case that the mask plate is not stretched.

It can be seen that, during the application, it is merely required to slide the sliding block in the case that the mask plate is not stretched, without removing the mask plate or replacing the mask plate, and thus the operation is very simple and the mask plate may be saved during the manufacturing process of the OLED panel.

To be specific, the frame for mounting mask plates in some embodiments of the present disclosure may have different types of structures, and the method for mounting the same may be varied accordingly. The present disclosure will be described hereinafter in conjunction with drawings and embodiments.

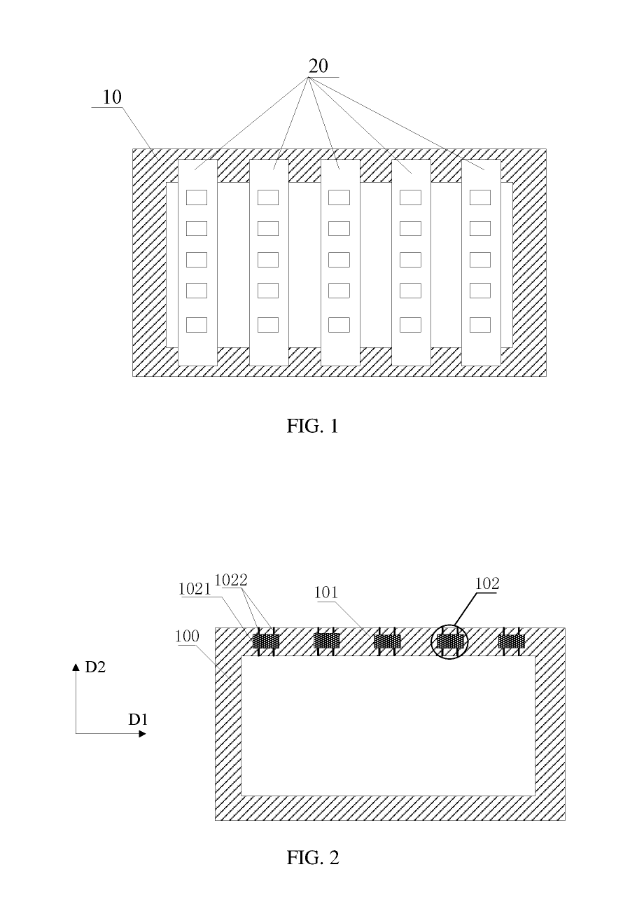

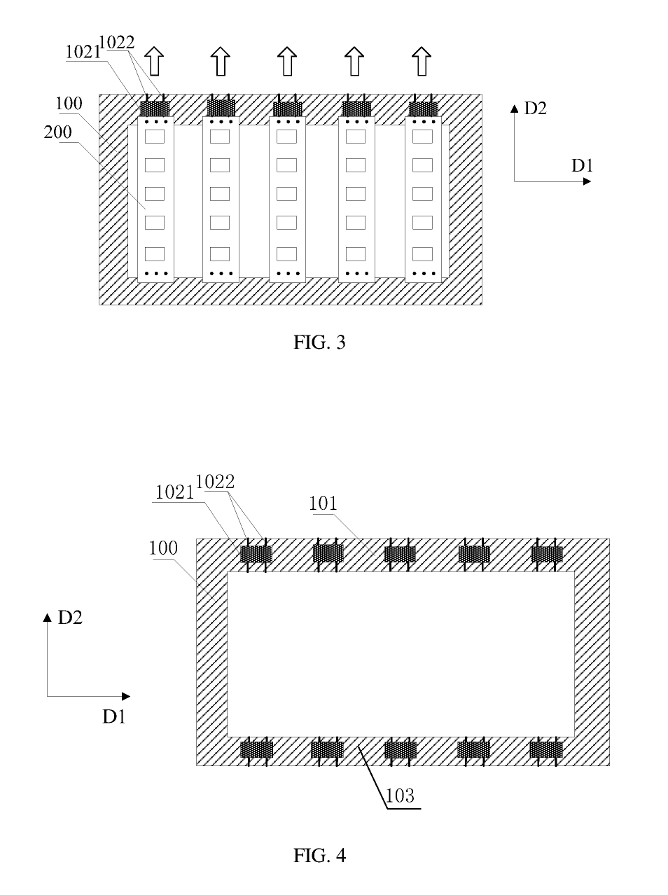

As shown in FIGS. 2 and 3, the frame for mounting mask plates in some embodiments of the present disclosure includes a frame body 100 and a plurality of pulling units 102 arranged at a first border portion 101 of the frame body 100. The mask plate 200 is fixed onto the first border portion 101. Each of the pulling units 102 includes a sliding block 1021 for connecting the mask plate 200 and a guide mechanism 1022 through which the sliding block 1021 slides along a direction perpendicular to the first border portion 101.

When mounting the mask plate 200 to the frame for mounting mask plates, an end of the mask plate 200 may be fixed onto the sliding block 1021 of the pulling unit 101 arranged at the first border portion 101, and then sliding block 1021 is slid along a direction of the arrow shown in FIG. 3, until the mask plate 200 is stretched. In compared with the assembling manner of the mask plate device shown in FIG. 1, it is not required to apply an external force to the frame body 100 to make it deformed towards its center or to maintain the external force until the welding of the mask plate 200 is completed. Therefore, the mounting process is very simple. In addition, during the application, it is merely required to slide the sliding block 1021 and then tense the mask plate 200 once more, without removing the mask plate 200, in the case that the mask plate 200 is not stretched. Therefore, the process of tightening the mask plate 200 once more is very simple. In addition, it is not required to replace the mask plate, thereby reducing the manufacturing cost of the OLED panel.

In some embodiments of the present disclosure, a plurality of pulling units 102 is arranged at each border portion of frame, so that a plurality of mask plates 200 may be mounted onto the frame. Of course, it is also feasible to arrange only one pulling unit 102 at each border portion of frame connected to the mask plate 200. The number of the pulling unit 102 arranged at each border portion of frame connected to the mask plate 200 may be determined as needed, which will be not be limited herein.

In some embodiments of the present disclosure, the specific structure of the guide mechanism 1022 is not limited, which may be a guide rail formed on the frame body 100 or a guide slot formed in the frame body 100. The guide rail formed on the frame body 100 may be a bump guide rail or a guide groove or other types of guide rail.

In some embodiments of the present disclosure, the pulling unit 102 may further include a fixing component arranged on the sliding block 1021 and configured to the fix the mask plate 200 onto the sliding block 1021.

The material of the sliding block is not limited in the case that the mask plate 200 is fixed onto the sliding block 1021 through the fixing component hereinabove. The type of the fixing component is not limited herein, which may be a clip, a bolt and so on. Of course, in the practical application, the fixing component may not be indispensable to the sliding block 1021. For example, the sliding block 1021 may be made of a metal material applicable to be welded to the mask plate 200, and then the mask plate 200 may be welded onto the sliding block 1021 directly.

To be specific, the frame for mounting mask plates in some embodiments of the present disclosure may further include a driving mechanism configured to drive the sliding block hereinabove to slide. Furthermore, the driving mechanism herein may be manually driven. For example, the driving mechanism may include a leading screw and a twisting handle connected to the leading screw. The leading screw is driven to rotate by the twisting handle, and then the leading screw is rotated so as to slide the sliding block, thereby driving the sliding block. Alternatively, the driving mechanism may be as shown in FIG. 6, which includes a leading screw 104 and a servo motor 105 connected to the leading screw 104 and configured to drive the leading screw 104. When mounting the mask plate, the servo motor is driven to rotate, so as to drive the leading screw 104 to rotate, and then the sliding block 1021 is driven by the leading screw 104 to slide along the guide mechanism 1022. According to such motor driving, the mounting of the mask plate may not be implemented manually, and the sliding block 1021 may be maintained at a certain position after the motor 105 stops working, without fixing the sliding block 1021.

In some embodiments of the present disclosure, the sliding block may further be slid and fixed manually in the case that no corresponding driving mechanism is arranged, and then the corresponding technical solution, which may also solve the issues in the related art, also fall within the scope of the present disclosure.

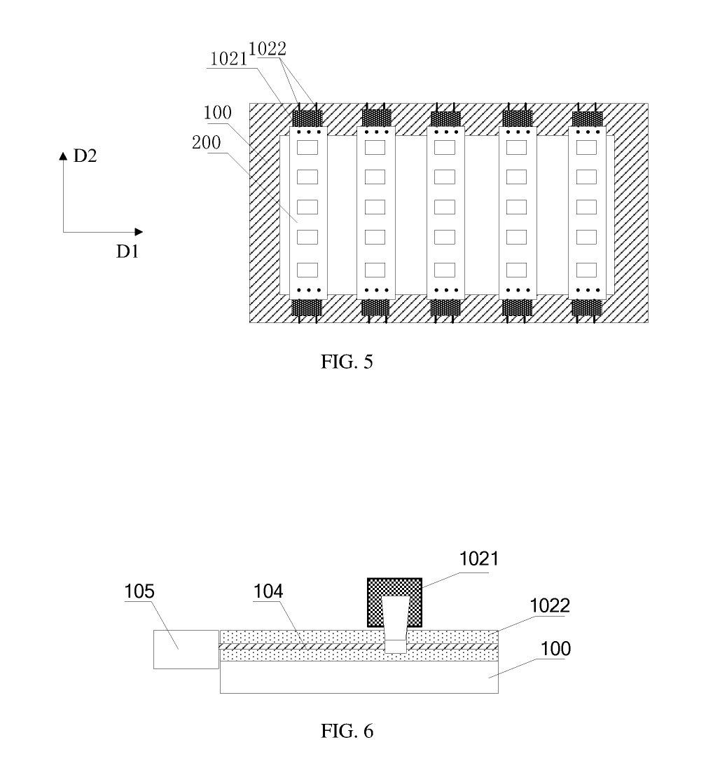

FIGS. 4 and 5 shows the frame for mounting mask plates in some embodiments of the present disclosure. In compared with the frame shown in FIGS. 2 and 3, the frame shown in each of FIGS. 4 and 5 further includes pulling units arranged at a second border portion 103 of the frame body 100. The second border portion 103 is parallel to the first border portion 101. Each pulling unit at the second border portion is opposite to one pulling unit at the first side border portion.

According to arrangement of the pulling unit hereinabove, the mask plate 200 may be stretched further. Each of the border portions of the frame body 100, onto which the mask plate is fixed, has a limited width, so each of the sliding blocks 1021 arranged at one border portion may be slid for a relatively short distance. By arranging the pulling units at both of the border portions opposite to each other, the mask plate 200 may be double stretched.

A mask plate device including the frame for mounting mask plates hereinabove is further provided in some embodiments of the present disclosure. In some embodiments of the present disclosure, as shown in FIG. 3, the mask plate device includes a frame for mounting mask plates and a mask plate 200 arranged at the frame in a movable manner. The frame for mounting mask plates may be the one described hereinabove, which may include a frame body and at least one pulling unit arranged on the frame body. The frame body includes a first border portion 101 for connecting a first end of the mask plate 200 and a second border portion 103 for connecting a second end of the mask plate 200. The first and second ends are the two ends of the mask plate 200 respectively. The first border portion 101 is substantially parallel to the second border portion 101. In some embodiments of the present disclosure, as shown in FIGS. 2 and 3, the first border portion 101 is strip-like and extends along a first direction D1, and each of the mask plates 200 is arranged along a second direction D2. The first direction D1 is substantially perpendicular to the second direction D2. In some embodiments of the present disclosure, a plurality of mask plates 200 are arranged at intervals along the first direction D1 and are parallel to each other. The two ends of each of the mask plates 200 along the second direction D2 are mounted onto the first and the second border portions respectively.

As shown in FIGS. 2 and 3, a plurality of pulling units 102 is arranged at the first border portion 101, and the pulling units 102 are in one-to-one correspondence with the mask plates 200. The first end of each of the mask plates 200 is connected to the sliding block of the corresponding pulling unit 102 at the first border portion, and the second end thereof is welded onto the second border portion 103. The first end of each of the mask plates 200 may be fixed onto the sliding block by welding or may be mounted onto the sliding block in a detachable manner, e.g., mounted through a bolt.

In some embodiments of the present disclosure, as shown in FIGS. 4 and 5, a plurality of pulling units 102 is arranged at both the first border portion 102 and the second border portion 103, and the pulling units 102 at the first border portion 101 are in one-to-one correspondence with the pulling units 102 at the second border portion 103. The first end of each of the mask plates 200 is connected to the sliding block of the corresponding pulling unit 102 at the first border portion 101, and the second end of each of the mask plates 200 is connected to the sliding block of the corresponding pulling unit 102 at the second border portion 103. Both of the first and second ends of each of the mask plates 200 may be fixed onto the sliding blocks by welding or mounted onto the sliding blocks in a detachable manner, e.g., mounted through bolts.

By moving the sliding blocks along the second direction D2, the mask plates 200 may be stretched or the tension applied to the mask plate 200 may be released along the second direction D2. For example, during a transport or a preservation process, the sliding blocks may be moved along the second direction D2, so as to release the tension applied to the mask plates 200. During application, the mask plates 200 may be tightened along the second direction D2 by moving the sliding blocks along the second direction D2. Therefore, the tightened mask plates 200 may not be broken during the transport or the preservation process by collision and so on, and the service life of the mask plates 200 may not be shortened since the tension applied to the mask plates 200 can be released.

In the present disclosure, such words as “first” and “second” used in the specification are merely for illustration, rather than to imply or indicate the importance. Such word as “a plurality of” refers to two or more than two, unless otherwise specified.

Although the embodiments are described above in conjunction with drawings, a person skilled in the art may make further modifications and alternations without departing from the principle of the present disclosure, and these modifications and alternations shall also fall within the scope of the present disclosure.

What is claimed is:

1. A frame for mounting a mask plate, comprising:
a frame body; and
at least one pulling unit at a first border portion of the frame body;
wherein the pulling unit comprises a sliding block for connecting the mask plate and a guide mechanism through which the sliding block slides along a direction perpendicular to the first border portion; and the first border portion is configured to install the mask plate.

2. The frame according to claim 1, further comprising at least one pulling unit at a second border portion of the frame body;
wherein the second border portion is parallel to the first border portion; the at least one pulling unit at the second border portion aligns with the at least one pulling unit at the first side border portion.

3. The frame according to claim 2, wherein there exists a plurality of pulling units at both the first and second border portions.

4. The frame according to claim 1, wherein the guide mechanism comprises a guide rail on the frame body.

5. The frame according to claim 1, wherein the sliding block is made of metal.

6. The frame according to claim 1, wherein the pulling unit further comprises a fixing component on the sliding block and configured to fix the mask plate onto the sliding block.

7. The frame according to claim 1, wherein the pulling unit further comprises a driving mechanism configured to drive the sliding block to slide.

8. The frame according to claim 7, wherein the driving mechanism comprises a leading screw and a twisting handle connected to the leading screw.

9. The frame according to claim 7, wherein the driving mechanism comprises a leading screw and a servo motor connected to the leading screw.

10. A method for fixing a mask plate using the frame according to claim 1, comprising:
fixing an end of the mask plate onto the sliding block of the pulling unit at the first border portion; and
sliding the sliding block until the mask plate is tightened.

11. The method according to claim 10, further comprising:
when the mask plate is loose, sliding the sliding block until the mask plate is tightened.

12. A mask plate device, comprising:
a frame for mounting a mask plate; and
at least one mask plate movably installed on the frame;
wherein the frame comprises a frame body with a first border portion and a second border portion, and at least one pulling unit at the first border portion;
the pulling unit comprises a guide mechanism at the first border portion and a sliding block slidably installed on the guide mechanism;
the mask plate comprises a first end connected to the sliding block and a second end connected to the second border portion.

13. The device according to claim 12, wherein the first border portion is parallel to the second border portion.

14. The device according to claim 12, wherein the first end of the mask plate is connected to the sliding block by welding.

15. The device according to claim 12, wherein the first end of the mask plate is detachably connected to the sliding block.

16. The device according to claim 12, wherein the frame further comprises at least one pulling unit at the second border portion;
wherein the pulling unit at the second border portion comprises a guide mechanism at the second border portion and a sliding block slidably installed on the guide mechanism at the second border portion;
the second end of the mask plate is connected to the sliding block at the second border portion.

17. The device according to claim 16, wherein the first end of the mask plate is detachably connected to the sliding block at the first border portion, and the second end of the mask plate is detachably connected to the sliding block at the second border portion.

18. The device according to claim 12, wherein the pulling unit further comprises a driving mechanism configured to drive the sliding block to slide.

19. The device according to claim 18, wherein the driving mechanism comprises a leading screw and a twisting handle connected to the leading screw;
wherein the sliding block is provided with a nut sleeved on the leading screw.

20. The device according to claim 18, wherein the driving mechanism comprises a leading screw and a servo motor connected to the leading screw;
wherein the sliding block is provided with a nut sleeved on the leading screw.
